(19) United States
(12) Patent Application Publication
(10) Pub. No.: US 2026/0040718 A1
(43) Pub. Date: Feb. 5, 2026

(54) SINGLE-PHOTON DETECTOR AND MANUFACTURING METHOD THEREFOR

(71) Applicant: WUHAN XINXIN SEMICONDUCTOR MANUFACTURING CO., LTD., Wuhan (CN)

(72) Inventor: Danqing WEI, Wuhan (CN)

(21) Appl. No.: 18/996,526

(22) PCT Filed: Nov. 24, 2022
(86) PCT No.: PCT/CN2022/133860

§ 371 Date: Jan. 17, 2025

(30) Foreign Application Priority Data
Aug. 31, 2022 (CN) 202211060479.9

(51) Int. Cl. H10F 77/20; H01L 21/306; H10F 30/225; H10F 39/10

(52) U.S. Cl. CPC H10F 77/206; H01L 21/30604; H01L 21/30625; H10F 30/225; H10F 39/107

(57) ABSTRACT

A method of manufacturing single-photon detector includes forming a first electrode on a front side of a substrate, removing the substrate and preforming ion implantation on a backside of an epitaxial layer to form a contact region for a second electrode, which extends from the surface of the epitaxial layer to a first predetermined depth within the epitaxial layer. The second electrode is be electrically connected to the contact region for the second electrode. Since the substrate is removed, the epitaxial layer, which is provided as a semiconductor layer, has a uniform thickness. The contact region for the second electrode has a uniform thickness, and its dopant concentration is easy to control and adjust. Thus, the second electrode can be formed so as to have uniform contact resistance across its different regions.

### TECHNICAL FIELD

The present invention relates to the field of semiconductor technology and, in particular, to a single-photon detector and a method of manufacturing the detector.

### BACKGROUND

A single photon avalanche diode (SPAD) is a solid-state device for photoelectric detection based on a reverse bias voltage higher than a breakdown voltage of a p-n junction therein. The p-n junction in the SPAD is reversely biased at a voltage higher than its breakdown voltage, allowing an avalanche current to develop due to the internal photoelectric effect (the liberation of electrons or another species of current carriers from a material stricken by photons). SPADs can detect very weak signals, for example, those with strength as low as that of a single-photon detector. SPAD-based single-photon detectors can be used for photon capture with high sensitivity and have found extensive use, for example, in fluorescence lifetime imaging (FLIM), 3D imaging and other applications.

At present, SPADs formed based on semiconductor substrates are typically vertical diodes. That is, two doped regions of such a diode are vertically arranged one above the other. The electrodes of a vertical diode may be arranged both on the front side, or on the front side and backside, respectively, of a substrate. For the former arrangement, in order to ensure that the diode is broken down essentially in the vertical direction, contact regions for the electrodes both on the front side of the substrate must be isolated, or spaced at a sufficient distance, from each other. However, as pixel arrays in more advanced single-photon detectors are required to have higher pixel densities, area shrinkage of individual SPADs is desirable. Arranging the two electrodes both on the front substrate side is not conducive to such shrinkage because a sufficient spacing between their contact regions must be ensured, compared with the latter arrangement with the two electrodes being arranged on the front side and backside of the substrate, respectively. That is, a pixel array with a higher pixel density can be more easily achieved with the latter arrangement.

Nevertheless, currently, the arrangement with the two electrodes being arranged on the front side and backside of the substrate, respectively, still suffers from the problem of inconsistent performance of the resulting device.

### SUMMARY

Referring to FIG. 1, in an existing SPAD design, in which the two electrodes are arranged on the front side and backside of a substrate, respectively, a contact region for the backside electrode 20 is usually a heavily-doped (e.g., p+) region of the substrate 10, and an epitaxial layer 30 on the front side of the substrate 10 contains doped regions, in which a depletion layer 31 of the diode is formed (e.g., between a p-well (PW) and an n-well (NW) therein). However, since the substrate 10 typically has been thinned using a regular grinding process and therefore has suboptimal uniformity (e.g., in contrast to a target thickness of 1 μm, the actual thickness may vary within the range of 1.6 μm to 0.4 μm), contact resistance of the backside electrode 20 tends to be non-uniform. Moreover, due to the thickness non-uniformity of the substrate 10, photogenerated current carriers in different regions will diffuse different distances into the depletion layer 30 during operation of the diode. Consequently, the SPAD and a single-photon detector, in which it is incorporated, would exhibit poor uniformity and inconsistent performance.

The present invention provides a method of manufacturing a single-photon detector incorporating an SPAD. Both the SPAD and the single-photon detector have improved uniformity and performance consistency.

In one aspect, the present invention provides a method of manufacturing a single-photon detector, including:
providing a semiconductor layer including a substrate and an epitaxial layer formed on a surface of the substrate, the epitaxial layer being of a first doping type;
forming doped regions of a diode, which are contiguous to each other, in the epitaxial layer and a first electrode on a front side of the epitaxial layer, wherein the first electrode is electrically connected to one of the contiguous doped regions of the diode;
removing the substrate;
implanting ions of the first doping type to the epitaxial layer from its backside to form a contact region for a second electrode, which extends from the backside of the epitaxial layer to a first predetermined depth within the epitaxial layer; and
forming the second electrode in the contact region for the second electrode so that the second electrode is electrically connected to the contact region for the second electrode.

Optionally, the removal of the substrate may include:
thinning the substrate using a chemical mechanical polishing (CMP) process so that a partially thickness of the substrate is retained; and
removing the remainder of the substrate using a wet etching process, wherein the substrate has a higher dopant concentration of the first doping type than the epitaxial layer, and the epitaxial layer serves as an etch stop layer in the wet etching.

Optionally, before the second electrode is formed, the method may further include:
etching the epitaxial layer from the backside, thereby forming a trench peripheral to the doped regions of the diode;
implanting ions of the first doping type to a side wall of the trench, thereby forming a first doped region extending from the side wall of the trench to a second predetermined depth in the epitaxial layer; and
filling an isolation material in the trench, thereby forming a trench isolation structure.

Optionally, the first doping type may be p-type, wherein the implantation of ions of the first doping type on the side wall of the trench may be accomplished in the same step as that on the backside of the epitaxial layer.

Optionally, following the implantation of ions of the first doping type on the side wall of the trench and on the backside of the epitaxial layer, the implanted ions may be activated by laser activation.

Optionally, the formation of the second electrode in the contact region for the second electrode may include:
forming at least one opening in the contact region for the second electrode;
depositing a conductive material on the contact region for the second electrode, which fills the opening and covers the contact region for the second electrode; and
patterning the conductive material, thereby forming the second electrode.

Optionally, a depth of the opening may be smaller than the first predetermined depth.

In another aspect, the present invention provides a single-photon detector including at least one (SPAD each including:
an epitaxial layer of a first doping type, which includes a front side and an opposite backside;
doped regions formed in the epitaxial layer, which are contiguous to each other;
a contact region for a second electrode, which is formed at the backside of the epitaxial layer, extends from the surface of the epitaxial layer to a first predetermined depth in the epitaxial layer, is of the same doping type as the epitaxial layer and has a higher dopant concentration than the epitaxial layer; and
a first electrode and a second electrode, which are disposed on the front side and backside of the epitaxial layer, respectively, the first electrode electrically connected to one of the doped regions, the second electrode formed in, and electrically connected to, the contact region for the second electrode.

Optionally, the doped regions may include a well of a second doping type and a well of the first doping type, which are vertically stacked within the epitaxial layer one above another, the well of the second doping type extending from a depth in the epitaxial layer to the front side of the epitaxial layer and electrically connected to the first electrode, the well of the first doping type being contiguous to a side of the well of the second doping type away from the first electrode, wherein the contact region for the second electrode is spaced from the well of the first doping type at a vertical distance greater than 0.

Optionally, the single-photon detector may include a plurality of the SPADs, wherein trench isolation structures are formed between adjacent ones of the SPADs, each trench isolation structure including a trench extending through the epitaxial layer along its thickness, the trench being filled with an isolation material, and wherein first doped regions are formed, which extend from side walls of the trenches to a second predetermined depth in the epitaxial layers.

The method of the present invention offers the benefits as follows:
1) The first and second electrodes are formed on the front side and backside of the epitaxial layer, respectively. In contrast to forming both electrodes on the front side, this allows a smaller area of the front side to be occupied, facilitating additional shrinkage of the SPAD for an increase in pixel density of the single-photon detector.
2) In addition to possible further shrinkage of the SPAD, forming the second electrode on the backside of the epitaxial layer allows the SPAD to have a high fill factor, which can avoid a compromise of the device's photon detection efficiency.
3) Through completely removing the substrate, the remainder of the semiconductor layer, i.e., the epitaxial layer, has a more uniform thickness, which enables more uniform absorption of photons and a more uniform distance of travel of photogenerated current carriers to the epitaxial layer, across different regions of the epitaxial layer, helping in enhancing the device's uniformity and performance consistency.
4) Since the contact region for the second electrode is formed by implanting ions of the first doping type to the epitaxial layer from the backside thereof, it has a uniform depth and a dopant concentration easy to control and adjust. Therefore, the second electrode has adjustable, uniform contact resistance across its different regions, helping enhance the uniformity and performance consistency of the resulting SPAD and the single-photon detector.
5) The implantation of ions of the first doping type for forming the contact region for the second electrode may be accomplished in the same step as that on the side wall of the trench isolation structure. Therefore, a step can be saved, resulting in a reduction in cost.

In the single-photon detector of the present invention, the epitaxial layer is a semiconductor layer having a more uniform thickness, which enables uniform absorption of photons and a uniform travel distance of photogenerated current carriers, across different regions of the epitaxial layer. Therefore, the SPAD and single-photon detector have improved uniformity and consistent performance. Moreover, since the contact region for the second electrode is formed by implanting ions of the first doping type to the epitaxial layer from its backside, it has a uniform depth and a dopant concentration easy to control and adjust. Thus, the second electrode can be formed in the contact region for the second electrode so as to have adjustable, uniform contact resistance across its different regions, helping enhance the uniformity and performance consistency of the SPAD and the single-photon detector.

### BRIEF DESCRIPTION OF THE DRAWINGS

FIG. 1 shows a schematic cross-sectional view of a conventional single-photon avalanche diode (SPAD).

FIG. 2 shows a flowchart of a method of manufacturing a single-photon detector according to embodiments of the present invention.

FIGS. 3A to 3J are schematic cross-sectional views of structures resulting from process steps in a method of manufacturing a single-photon detector according to an embodiment of the present invention.

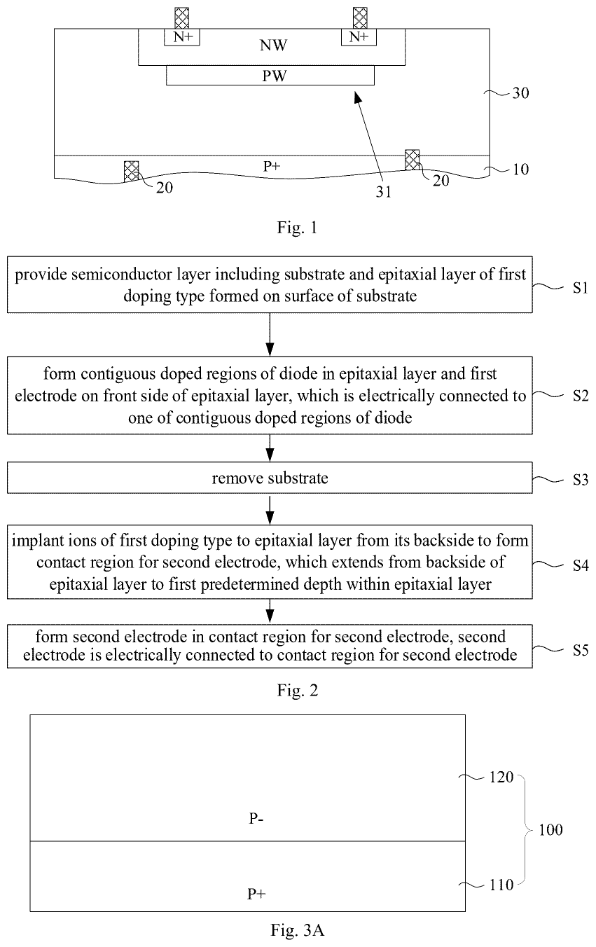

### LIST OF REFERENCE NUMERALS

10, 110 substrate; 20 backside electrode; 31 depletion layer; 30, 120 epitaxial layer; 100 semiconductor layer; 101 implantation of ions of first doping type; 121 well of second doping type; 122 well of first doping type; 123 contact region for first electrode; 124 trench; 124a p-doped region; 125 contact region for second electrode; 126 trench isolation structure; 127 opening; 130 first electrode; 140 second electrode; 141 conductive material.

### DETAILED DESCRIPTION

Single-photon detectors and methods according to the present invention will be described in greater detail below with reference to the accompanying drawings, which illustrate specific embodiments thereof. From the following description, advantages and features of the present invention will be more apparent. It will be understood that the figures are provided in a very simplified form not necessarily drawn to exact scale for the only purpose of helping to explain the disclosed embodiments in a more convenient and clearer way.

It is to be noted that the terms “first”, “second” and the like may be used herein to distinguish between similar elements without necessarily implying any particular ordinal or chronological sequence. It will be understood that the terms so used are interchangeable, whenever appropriate, such that, for example, the embodiments of the invention described herein are capable of operation in sequences other than those illustrated or otherwise described herein. Likewise, if a method is described herein as including a series of steps, the order of these steps as presented herein is not necessarily the only order in which they can be performed, and certain ones of the stated steps may be possibly omitted and/or certain other steps not described herein may be possibly added to the method. It will be understood that, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

Embodiments of the present invention relate to a method of manufacturing a single-photon detector. Referring to FIG. 2, the method includes the steps of:
S1) providing a semiconductor layer including a substrate and an epitaxial layer formed on a surface of the substrate, the epitaxial layer being of a first doping type;
S2) forming doped regions of a diode, which are contiguous to each other, in the epitaxial layer and a first electrode on a front side of the epitaxial layer, wherein the first electrode is electrically connected to one of the contiguous doped regions of the diode;
S3) removing the substrate;
S4) implanting ions of the first doping type to the epitaxial layer from its backside to form a contact region for a second electrode, which extends from the backside of the epitaxial layer to a first predetermined depth in the epitaxial layer; and
S5) forming the second electrode in the contact region, the second electrode is electrically connected to the contact region.

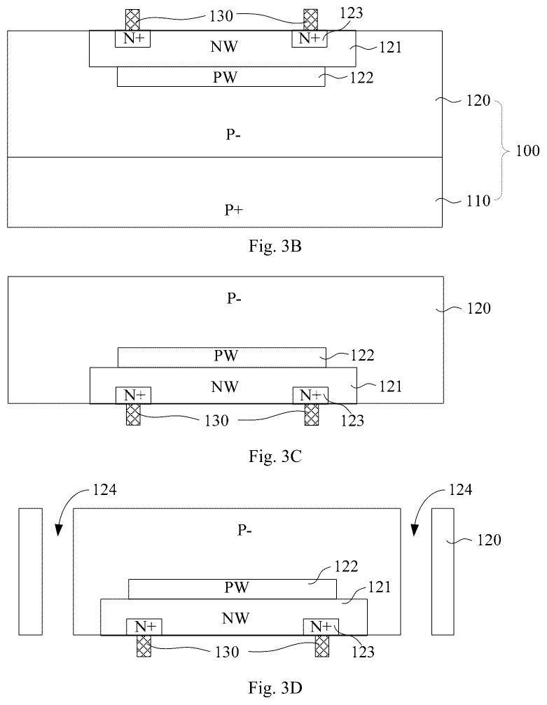

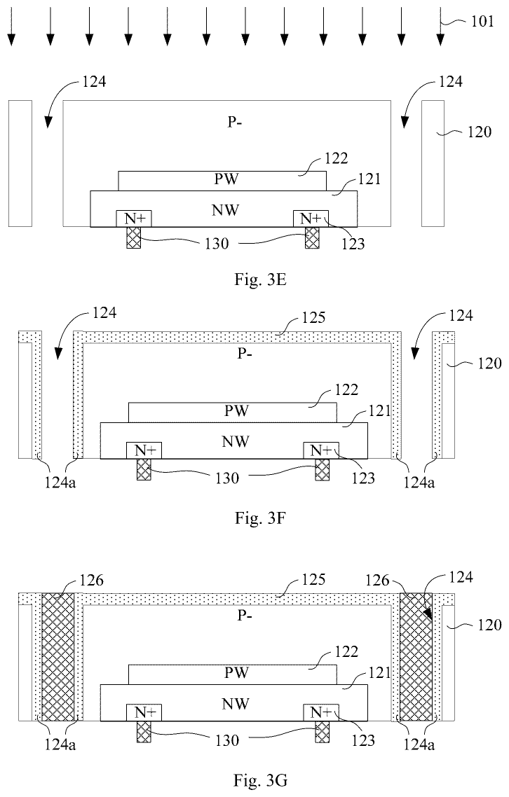

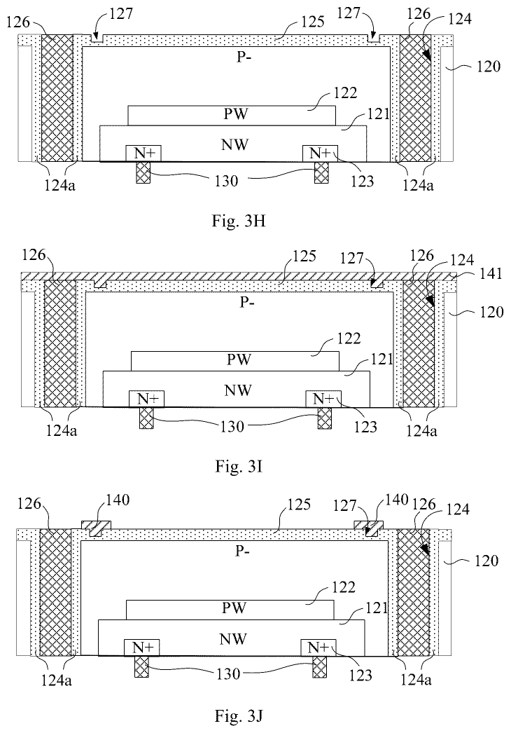

A method of manufacturing a single-photon detector according to an embodiment of the present invention is described in detail below with reference to FIGS. 3A to 3J.

First of all, reference is made to FIG. 3A. In step S1, a semiconductor layer 100 is provided. In this embodiment, the semiconductor layer 100 includes a substrate 110, which is, for example, a silicon substrate. An epitaxial layer 120 is formed on a front side of the silicon substrate, which is opposite to a backside of the substrate 110. The epitaxial layer 120 has a backside, which is a surface thereof facing toward the substrate 110, and a front side, which is a surface of the epitaxial layer 120 facing away from the substrate 110.

In this embodiment, the substrate 110 is heavily-doped, and the epitaxial layer 120 is a lightly-doped layer grown on the substrate 110. Optionally, the substrate 110 may be a heavily-doped substrate of a first doping type, for example, a heavily-doped p-type (p+) substrate, and the epitaxial layer 120 may be a lightly-doped layer also of the first doping type, for example, a lightly-doped p-type (p-) layer. A p-type dopant concentration of the substrate 110 is higher than a p-type dopant concentration of the epitaxial layer 120. The p-type dopant concentration of the epitaxial layer 120 may be, for example, higher than or equal to 5×10′⁶/cm³ and lower than or equal to 5×10¹⁸/cm³. The p-type dopant concentration of the substrate 110 may be, for example, higher than or equal to 1×10¹⁹/cm³ and lower than or equal to 1×10²¹/cm³. In other embodiments, the substrate 110 may also include other materials. When the first doping type is n-type (e.g., doping with phosphorus (P) or arsenic (As)), a second doping type is p-type (e.g., doping with boron (B) or boron difluoride (BF₂)). When the first doping type is p-type, the second doping type is n-type. The following description is set forth in the context of the first doping type being p-type and the second doping type being n-type, as an example. However, it would be appreciated that, without departing from the scope of the present invention, the first and second doping types may alternatively be n-type and p-type, respectively.

Next, referring to FIG. 3B, in step S2, in the epitaxial layer 120, doped regions of a diode are formed, which are contiguous to each other. The contiguous doped regions include a p-doped region and an n-doped region, which provide a p-n junction and a depletion layer of a single-photon avalanche diode (SPAD). Multiple lateral pairs of such contiguous doped regions for respective SPADs may be formed in the epitaxial layer 120 (only one pair is shown in FIG. 3B, as an example).

Referring to FIG. 3B, in this embodiment, the doped regions formed in the epitaxial layer 120 include a well 121 of the second doping type (an n-well, in this embodiment) and a well 122 of the first doping type (a p-well, in this embodiment), which are vertically stacked one above the other in the epitaxial layer 120. The well 121 of the second doping type extends from a depth in the epitaxial layer 120 to the front side of the epitaxial layer 120, and the well 122 of the first doping type contiguous to a side of the well 121 of the second doping type facing away from the front side of the epitaxial layer 120. In some other embodiments, instead of being vertically stack one above the other, the wells of the second and first doping types may also be laterally contiguous to each other in the epitaxial layer 120 (i.e., arranged side-by-side in a direction parallel to the front side of the epitaxial layer 120), or obliquely contiguous to each other (i.e., arranged side-by-side in a direction forming an acute angle with the front side of the epitaxial layer). Still alternatively, one of the two well may surround the other (e.g., the well of the first doping type may surround the well of the second doping type). The well 121 of the second doping type and the well 122 of the first doping type may be formed by implanting corresponding ions to corresponding regions of the epitaxial layer 120 from its front side and then activating the implanted ions. The contiguous doped regions in the epitaxial layer 120 may be formed otherwise. For example, in some other embodiments, a well of the first doping type may be first formed in the epitaxial layer 120, and a heavily doped region of the second doping type may be then formed on top of the well of the first doping type. In these cases, the well of the first doping type and the heavily doped region of the second doping type may provide the aforementioned contiguous doped regions.

Referring to FIG. 3B, in step S2, a first electrode 130 is further formed on the front side of the epitaxial layer 120. The first electrode 130 is electrically connected to one of the contiguous doped regions. In this embodiment, the well 121 of the second doping type extends from a depth in the epitaxial layer 120 to the front side of the epitaxial layer 120, and the first electrode 130 is electrically connected to the well 121 of the second doping type. In case of multiple pairs of doped regions, such a first electrode 130 may be formed on the front side of the epitaxial layer 120 for each pair.

Optionally, in the well 121 of the second doping type, at least one contact region 123 for the first electrode may be formed, each of which extends from the surface of the well 121 of the second doping type and terminates in the well 121 of the second doping type. The contact region 123 for first electrode is a heavily-doped region of the second doping type (labeled as N+), and the first electrode 130 may be electrically connected to the well 121 of the second doping type via the contact region 123 for first electrode, reducing the contact resistance of the first electrode 130. Within the same well 121 of the second doping type, one or more contact regions 123 for first electrode may be formed for the first electrode. The formation of the contact regions 123 for first electrode may be accomplished by implanting ions through masks to corresponding regions of the well 121 of the second doping type and then activating the implanted ions. In order to form the first electrode 130, an interlayer dielectric layer (not shown) on the epitaxial layer 130, and then a hole extending through the interlayer dielectric layer, may be formed. The first electrode 130 may be formed in the through hole in the interlayer dielectric layer so as to be electrically connected to the contact region 123 for first electrode.

After that, referring to FIG. 3C, in step S3, the substrate 110 is removed. Depending on a thickness of the substrate 110 and possibly other factors, a suitable removal method may be chosen. In this embodiment, after step S2 is completed, the thickness of the substrate 110 is 500 μm or more. In an efficient process, the substrate 110 may be first thinned from the backside by chemical mechanical polishing (CMP), and a part thickness of the substrate 110 is remained, the remainder of the substrate 110 is then completed removed by wet etching. Compared with removing the entire substrate 110 by wet etching, this allows a reduced amount of an etchant solution to be used and shorten the time required for etching. The substrate 110 that remains from the CMP process and is removed by wet etching may have a suitable thickness (e.g., greater than 5 μm, more preferably 10 μm). This can avoid surface unevenness and undesired partial removal of the epitaxial layer 120, which may be otherwise introduced by the CMP process, as well as undesired significant etching of the epitaxial layer 120 in the wet etching process due to an insufficient thickness of the remainder. During the removal, since the substrate 110 is required to be oriented with the backside of the substrate 110 facing upwards, optionally, a protective layer may be formed on, or a temporary support substrate (not shown) may be bonded to, the front side of the epitaxial layer 120, if required, before the backside thinning process starts on the substrate 110.

In this embodiment, taking advantage of the dopant concentration of the first doping type of the substrate 110, which is higher than the dopant concentration of the first doping type of the epitaxial layer 120, the epitaxial layer 120 may serve as an etch stop layer in the wet etching process to remove the remainder of the substrate 110 resulting from the thinning process. As a result of step S3, the backside of the epitaxial layer 120 is exposed, and because the epitaxial layer 120 is less affected during the removal of the substrate 110, the epitaxial layer 120 has a uniform thickness.

Next, in step S4, ions of the first doping type (p-type, in this embodiment) are implanted to the epitaxial layer 120 from the backside thereof to form a contact region 125 for a second electrode (see FIG. 3F) on the backside of the epitaxial layer 120, which extends from the surface of the epitaxial layer 120 to a first predetermined depth in the epitaxial layer 120. Since the contact region 125 for the second electrode is formed by ion implantation through the epitaxial layer 120 of the first doping type, the contact region 125 for the second electrode is of the same doping type, i.e., the first doping type and has a higher dopant concentration than the epitaxial layer 120.

In order to isolate the SPAD being fabricated from adjacent SPADs to avoid crosstalk between them, the method of this embodiment may further include forming a trench isolation structure between the adjacent SPADs. Moreover, in order to achieve a lower dark-count rate, a first doped (p-doped, in this embodiment) region may be formed on a side wall of the trench isolation structure, which extends from the side wall to a second predetermined depth in the epitaxial layer 120. In order to save a step, the contact region 125 for the second electrode may be formed in the same step as the first doped region. The first predetermined depth may be equal to the second predetermined depth, or not.

Specifically, referring to FIG. 3D, step S4 may include the sub-steps described below.

At first, photolithography and etching processes are performed on the backside of the epitaxial layer 120 to form a trench 124 peripheral to the doped regions of the diode. In order for better isolation to be achieved, the trench 124 may be a deep trench (e.g., with a depth greater than 2000 Å), which may extend through the epitaxial layer 120 and expose the interlayer dielectric layer (not shown) on the front side of the epitaxial layer 120. In case of multiple SPADs being fabricated, when viewed from the backside of the epitaxial layer 120, multiple trenches 124 may be formed, for example, into a grid defining cells for the respective SPADs to be formed therein.

After that, referring to FIG. 3E, ions of the first doping type (p-type, in this embodiment) are implanted 101 to a side wall of the trench 124 and the backside of the epitaxial layer 120, the first doping type is p-type in this embodiment. The implantation of ions 101 of first doping type is p-type ions implantation and does not require the use of a mask, and the ion implantation may be performed at any suitable angle, as required. For example, the ions of the first doping type may be implanted with energy of 5 keV to 30 keV at a dose of 2×10¹/cm² to 3×10¹/cm².

Subsequently, referring to FIG. 3F, the implanted ions are activated to form a p-doped region 124a extending from the side wall of the trench 124 to a second predetermined depth in the epitaxial layer 120 and the contact region 125 for the second electrode on the backside of the epitaxial layer 120, which extends from the surface of the epitaxial layer 120 to the first predetermined depth in the epitaxial layer 120. If the activation is accomplished by overall heating, the doped regions of the diode being fabricated, which have been formed, would be adversely affected. Therefore, the implanted ions may be activated by laser activation.

Afterwards, referring to FIG. 3G, an isolation material is filled in the trench 124, forming a trench isolation structure 126. For example, a high-k dielectric layer (e.g., with a dielectric constant higher than 3.9; not shown) may be first deposited to line the trench 124, and another dielectric material with a lower dielectric constant may be deposited onto the high-k dielectric layer and fill the trench 124. The high-k dielectric layer can facilitate absorption of photogenerated current carriers near the trench 124, reducing crosstalk with adjacent SPADs. The high-k dielectric layer may include Al₂O₃, Ta₂O₅, ZrO₂, LaO, Si₃N₄, TiO₂ or any other suitable material. The dielectric material deposited on the high-k dielectric layer is preferred to be capable of blocking light and may include, for example, metal, polysilicon or the like. After the trench 124 is filled, the isolation material deposited above the backside of the epitaxial layer 120 may be removed using a grinding, etching or other process.

Next, in step S5, the second electrode 140 is formed in the contact region 125 for second electrode (see FIG. 3J), the second electrode 140 is electrically connected to the contact region 125. Specifically, step S5 may include the sub-steps described below.

First of all, photoresist is applied to the surface of the contact region 125 for second electrode and then exposed and developed to define a location where the backside electrode (i.e., the second electrode) to be brought into contact with the contact region 125 for second electrode.

Next, with the photoresist serving as a mask, the contact region 125 for second electrode is etched, forming at least one opening 127 in the contact region 125 for second electrode, followed by removal of the photoresist, as shown in FIG. 3H.

Subsequently, referring to FIG. 3I, a conductive material 141 is deposited on the contact region 125 for second electrode, the conductive material 141 fills the opening 127 and covers the contact region 125 for second electrode.

After that, referring to FIG. 3J, the conductive material 141 is patterned, forming the second electrode 140.

In this embodiment, in case of multiple SPADs being fabricated, multiple openings 127 may be formed in the contact region 125 for second electrode, in a cross section parallel to the epitaxial layer 120, the multiple openings 127 are formed between trench isolation structures 126 and the corresponding doped regions of the diodes to avoid second electrodes 140 to be formed in the openings from affecting incidence of light on the SPADs. Preferably, the opening 127 has a depth smaller than a thickness of the contact region 125 for second electrode, that is, the depth of the opening 127 is smaller than the first predetermined depth. In this way, a bottom surface of the second electrode 140 is located within the contact region 125 for second electrode. This is helpful in reducing the contact resistance of the second electrode 140.

In this embodiment, the deposition of the conductive material 141 on the contact region 125 for second electrode may involve: successively depositing an adhesive layer (e.g., titanium (Ti)), which lines the opening 127 and covers the contact region 125 for second electrode outside the opening 127, and a barrier layer (e.g., titanium nitride (TiN)) on the adhesive layer; and then depositing a metal material (e.g., aluminum (Al)), which covers the barrier layer and fills the opening 127. The adhesive layer is formed to enhance adhesion of the metal material to the epitaxial layer 120, and the barrier layer is formed to block diffusion of metal ions into the epitaxial layer 120 and prevent the metal material from undesirably reacting with the epitaxial layer 120 at a certain temperature.

Referring to FIG. 3J, after the conductive material 141 is patterned, the conductive material 141 in the opening 127 is retained as the second electrode 140. During the formation of the second electrode 140, a wiring structure may also be formed on the backside of the epitaxial layer 120 according to a wiring scheme for the second electrode 140. The wiring structure is formed to selectively connect the second electrode 140 in the opening 127 to one or more other second electrodes 140.

After the second electrode 140 is formed, an insulating layer may be deposited over the second electrode 140 and patterned to expose part of the second electrode 140 or the wiring structure connected to the second electrode 140, thereby forming a pad. The second electrode 140 may be connected to an external circuit through the pad.

Therefore, in the above method, after the first electrode 130 is formed on the front side of the epitaxial layer 120, the substrate 110 is removed, and ion implantation is performed on the backside of the epitaxial layer 120 to form the contact region 125 for the second electrode, which extends from the surface of the epitaxial layer 120 to the first predetermined depth within the epitaxial layer 120. Moreover, the second electrode is formed so as to be electrically connected to the contact region 125 for second electrode. Since the substrate 110 is totally removed, the remainder of the semiconductor layer, i.e., the epitaxial layer has a uniform thickness, which enables uniform absorption of photons and a uniform travel distance of photogenerated current carriers, across different regions of the epitaxial layer. Therefore, the resulting SPAD and single-photon detector have improved uniformity and consistent performance. Moreover, since the contact region 125 for the second electrode is formed by ion implantation after the substrate 110 is removed, it has a uniform depth and its dopant concentration is easy to control and adjust. Thus, the second electrode 140 can be formed so as to have uniform contact resistance across its different regions, helping enhance the uniformity and performance consistency of the SPAD and the single-photon detector. Further, the contact region 125 for the second electrode may be formed in the same step as the p-doped region 124a that extends from the side wall of the trench 124 to the second predetermined depth in the epitaxial layer 120, reducing the process cost and saving a step.

Embodiments of the present invention also relate to a single-photon detector obtainable according to the method as discussed above. Referring to FIG. 3J, the single-photon detector includes at least one single-photon avalanche diode (SPAD) each including:
an epitaxial layer 120 of a first doping type, which includes a front side and an opposite backside;
doped regions formed in the epitaxial layer 120, which are contiguous to each other;
a contact region 125 for a second electrode, which is formed at the backside of the epitaxial layer 120, extends from the surface of the epitaxial layer 120 to a first predetermined depth in the epitaxial layer 120, the contact region 125 for second electrode is of the same doping type as the epitaxial layer 120, the contact region 125 for second electrode has a higher dopant concentration than the epitaxial layer 120; and
a first electrode 130 and a second electrode 140, which are disposed on the front side and backside of the epitaxial layer 120, respectively, the first electrode 130 is electrically connected to one of the doped regions, the second electrode 140 is formed in the contact region 125 for second electrode and is electrically connected to the contact region 125 for second electrode.

The contiguous doped regions formed in the epitaxial layer 120 provide a p-n junction of the SPAD and a depletion layer at an interface of the p-n junction. The depletion layer will be broadened when a reverse bias voltage is applied. An avalanche current will be created in operation at a voltage above a breakdown voltage of the p-n junction. For example, the first doping type is p-type, and a second doping type is n-type.

The single-photon detector may include multiple such SPADs and trench isolation structures 126 formed between adjacent SPADs. Each trench isolation structure 126 is formed in a trench 124 extending through the epitaxial layer 120 along its thickness and includes an isolation material filled in the trench 124 and a first doped region (a p-doped region 124a, in this embodiment) extending from a side wall of the trenches 124 to a second predetermined depth in the epitaxial layer 120.

Optionally, the contiguous doped regions formed in the epitaxial layer 120 may include a well 121 of the second doping type (an n-well (NW), in this embodiment) and a well 122 of the first doping type (a p-well (PW), in this embodiment), which are vertically stacked one above the other within the epitaxial layer 120. The well 121 of the second doping type extends from a given depth in the epitaxial layer 120 to a front side of the epitaxial layer 120 and is electrically connected to the first electrode 130. The well 122 of the first doping type is contiguous to the side of the well 121 of the second doping type away from the first electrode 130. The contact region 125 for the second electrode is vertically spaced from the well 122 of the first doping type at a distance greater than 0. In some embodiments, a contact region 123 for the first electrode may be formed in the well 121 of the second doping type, the contact region 123 for the first electrode has a higher dopant concentration of the second doping type than the well 121 of the second doping type. The first electrode 130 may be electrically connected to the well 121 of the second doping type via the contact region 123 for first electrode.

The contact region 125 for the second electrode is formed at the backside of the epitaxial layer 120 and extends from the surface of the epitaxial layer 120 to the first predetermined depth in the epitaxial layer 120. The first predetermined depth may be about 100 Å to 500 Å. An opening 127 is formed in the contact region 125 for second electrode. The second electrode 140 is filled in the opening 127. The second electrode 140 may include a sequential stack of an adhesive layer (e.g., Ti), a barrier layer (e.g., TiN) and a metal material (e.g., Al), which lines the opening 127 and covers part of the epitaxial layer 120 outside the opening 127.

In this single-photon detector, the epitaxial layer 120 is a substrate layer having a more uniform thickness, which enables uniform absorption of photons and a uniform travel distance of photogenerated current carriers, across different regions of the epitaxial layer. Therefore, the SPAD and single-photon detector have improved uniformity and consistent performance. Moreover, the contact region 125 for the second electrode is formed at the backside of the epitaxial layer 120, the contact region 125 for the second electrode has a uniform depth and a dopant concentration easy to control and adjust. Thus, after the second electrode 140 is formed, different regions of the second electrode 140 have adjustable, uniform contact resistance, thereby helping enhance the uniformity and performance consistency of the SPAD and the single-photon detector.

It is to be noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A method of manufacturing a single-photon detector, comprising:
providing an epitaxial layer on a first doping type, which comprises a front side and a backside opposite to the front side;
forming doped regions of a diode in the epitaxial layer, which are contiguous to each other;
forming a contact region for a second electrode, which is formed at the backside of the epitaxial layer, extends from the surface of the epitaxial layer to a first predetermined depth in the epitaxial layer; and
forming a first electrode and a second electrode, which are disposed on the front side and the backside of the epitaxial layer, respectively, the first electrode electrically connected to one of the doped regions, the second electrode formed in, and electrically connected to, the contact region for the second electrode.

2. The method of claim 1, wherein providing the epitaxial layer comprises:
providing a semiconductor layer comprising a substrate and an epitaxial layer formed on a surface of the substrate;
thinning the substrate using a chemical mechanical polishing (CMP) process, and a partially thickness of the substrate is retained; and
removing the remainder of the substrate using a wet etching process with the epitaxial layer serving as an etch stop layer in the wet etching, wherein the substrate has a higher dopant concentration of the first doping type than the epitaxial layer.

3. The method of claim 1, further comprising, before the second electrode is formed:
etching the epitaxial layer from the backside, thereby forming a trench peripheral to the doped regions of the diode;
forming a first doped region extending from the side wall of the trench to a second predetermined depth in the epitaxial layer; and
filling an isolation material in the trench, thereby forming a trench isolation structure.

4. The method of claim 3, wherein the first doped region is formed in a same step as the contact region for the second electrode by performing ion implantation and ion activation processes.

5. The method of claim 4, wherein performing the ion implantation and the ion activation processes comprises:
implanting ions of the first doping type to a side wall of the trench and the backside of the epitaxial layer thereby forming the first doped region and the contact region for the second electrode, respectively; and
following the implantation of ions of the first doping type on the side wall of the trench and on the backside of the epitaxial layer, the implanted ions are activated by laser activation.

6. The method of claim 1, wherein the formation of the second electrode in the contact region for the second electrode comprises:
forming at least one opening in the contact region for the second electrode;
depositing a conductive material on the contact region for the second electrode, which fills the opening and covers the contact region for the second electrode; and
patterning the conductive material, thereby forming the second electrode.

7. The method of claim 6, wherein a depth of the opening is smaller than the first predetermined depth.

8. The method of claim 3, wherein the trench is a deep trench and extends through the epitaxial layer.

9. A single-photon detector, comprising at least one single-photon avalanche diode (SPAD) each comprising:
an epitaxial layer of a first doping type, which comprises a front side and a backside opposite to the front side;
doped regions of a diode formed in the epitaxial layer, which are contiguous to each other;
a contact region for a second electrode, which is formed at the backside of the epitaxial layer, extends from the surface of the epitaxial layer to a first predetermined depth in the epitaxial layer,
a first electrode and a second electrode, which are disposed on the front side and the backside of the epitaxial layer, respectively, the first electrode electrically connected to one of the doped regions, the second electrode formed in, and electrically connected to, the contact region for the second electrode.

10. The single-photon detector of claim 9, wherein the doped regions comprises a well of a second doping type and a well of the first doping type, which are vertically stacked within the epitaxial layer one above another, the well of the second doping type extending from a depth in the epitaxial layer to the front side of the epitaxial layer and electrically connected to the first electrode, the well of the first doping type being contiguous to a side of the well of the second doping type away from the first electrode, wherein the contact region for the second electrode is spaced from the well of the first doping type at a vertical distance greater than 0.

11. The single-photon detector of claim 9, comprising a plurality of the SPADs, wherein trench isolation structures are formed between adjacent ones of the SPADs, each trench isolation structure comprising a trench extending through the epitaxial layer along its thickness, the trench being filled with an isolation material, and wherein first doped regions are formed, which extend from side walls of the trenches to a second predetermined depth in the epitaxial layers.

12. The method of claim 3, wherein the second electrode is formed between the trench isolation structure and the corresponding doped regions of the diode.

13. The single-photon detector of claim 9, wherein the epitaxial layer is acquired by removing at least a portion of a substrate adjacent to the epitaxial layer using a wet etching process with the epitaxial layer serving as an etch stop layer in the wet etching, wherein the substrate has a higher dopant concentration of the first doping type than the epitaxial layer.

14. The single-photon detector of claim 11, wherein the first doped region is formed in a same step as the contact region for the second electrode by performing ion implantation and ion activation processes.

15. The single-photon detector of claim 11, wherein the second electrode is formed between one of the trench isolation structures and the corresponding doped regions of the diode.

16. The single-photon detector of claim 9, wherein a bottom surface of the second electrode is located within the contact region for the second electrode.

17. The single-photon detector of claim 9, wherein the contact region for the second electrode is of the same doping type as the epitaxial layer, the contact region for the second electrode has a higher dopant concentration than the epitaxial layer.
